(19) United States
(12) Patent Application Publication
(10) Pub. No.: US 2022/0399344 A1
(43) Pub. Date: Dec. 15, 2022

(54) Method of Fabricating Memory

(71) Applicant: CHANGXIN MEMORY TECHNOLOGIES, INC., Hefei City, Anhui (CN)

(72) Inventor: Haibin XIANG, Hefei City, Anhui (CN)

(21) Appl. No.: 17/595,610

(22) PCT Filed: Jun. 16, 2021
(86) PCT No.: PCT/CN2021/100380

§ 371 Date: Nov. 19, 2021

(30) Foreign Application Priority Data
Sep. 7, 2020 (CN) 202010929515.5

(51) Int. Cl. H01L 27/108

(52) U.S. Cl. CPC H01L 27/10876; H01L 27/10888

(57) ABSTRACT

Embodiments of the present application provide a method of fabricating a memory, the method comprises: providing a substrate, wherein grooves are disposed in the substrate; forming a gate insulation layer on a surface of each groove; forming a metal layer on the gate insulation layer, the metal layer being at least fully filled in the groove; surface-processing the metal layer, to enhance flatness of a surface of the metal layer; and etching to remove the metal layer by a certain thickness to form a gate electrode whose top is lower than a surface of the substrate. Embodiments of the present application facilitate to solve the problem of unevenness at the top surface of the gate electrode.

### CROSS-REFERENCE TO RELATED APPLICATIONS

The present application is based on and claims the right of priority of the Chinese patent application No. 202010929515.5 filed on Sep. 7, 2020, the entire contents thereof are herein incorporated by reference.

### TECHNICAL FIELD

The present application relates to the field of semiconductor fabrication techniques, and more particularly to a method of fabricating a memory.

### BACKGROUND

Dynamic random access memory is a semiconductor memory widely used in various computer systems. With the incessant decrease in feature sizes of semiconductor integrated circuit devices, the fabrication processing technique also becomes increasingly difficult, and the feature window between the gate electrode and the bitline contact hole is increasingly small.

In the state of the art, the top surface of the gate electrode is uneven, and this easily leads the gate electrode to short circuit with the bitline contact hole, thus causing damage to the entire circuit, so it is of particular importance to improve the flatness at the top surface of the gate electrode.

### SUMMARY

Embodiments of the present application provide a method of fabricating a memory, thus facilitating to solve the problem of unevenness at the top surface of the semiconductor gate electrode.

In order to solve the above problem, embodiments of the present application provide a method of fabricating a memory, and the method comprises: providing a substrate, wherein grooves are disposed in the substrate; forming a gate insulation layer on a surface of each groove; forming a metal layer on the gate insulation layer, the metal layer being at least fully filled in the groove; surface-processing the metal layer, to enhance flatness of a surface of the metal layer; and etching to remove the metal layer by a certain thickness to form a gate electrode whose top is lower than a surface of the substrate.

### BRIEF DESCRIPTION OF DRAWINGS

One or more embodiments is/are exemplarily illustrated via corresponding figures in the accompanying drawings. Component parts with identical reference numerals in the accompanying drawings stand for similar component parts. Unless otherwise specifically stated, figures in the accompanying drawings are not drawn to scale.

FIG. 1 is a diagram schematically illustrating partial structure of a memory; and

FIGS. 2˜12 are diagrams schematically illustrating structures to which various steps in the method of fabricating a memory as provided by the embodiments of the present application correspond.

### DESCRIPTION OF EMBODIMENTS

As can be known from the Background of the Related Art, the safety of prior-art memories is to be improved.

During the process of developing semiconductor integrated circuits, at the same time of gradually reducing the dimension of the smallest component elements obtainable by the processing technique, the number of interconnecting elements per unit wafer area is gradually increased, while the feature window reserved for each channel becomes increasingly smaller.

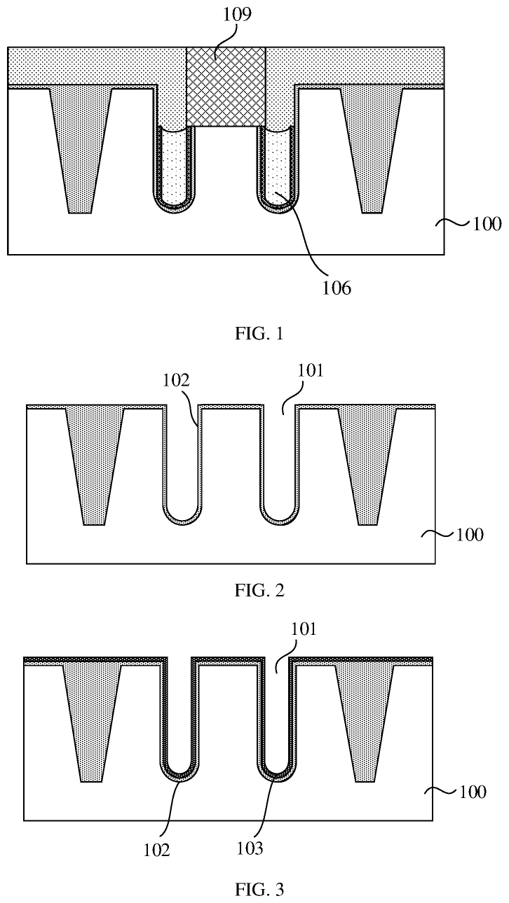

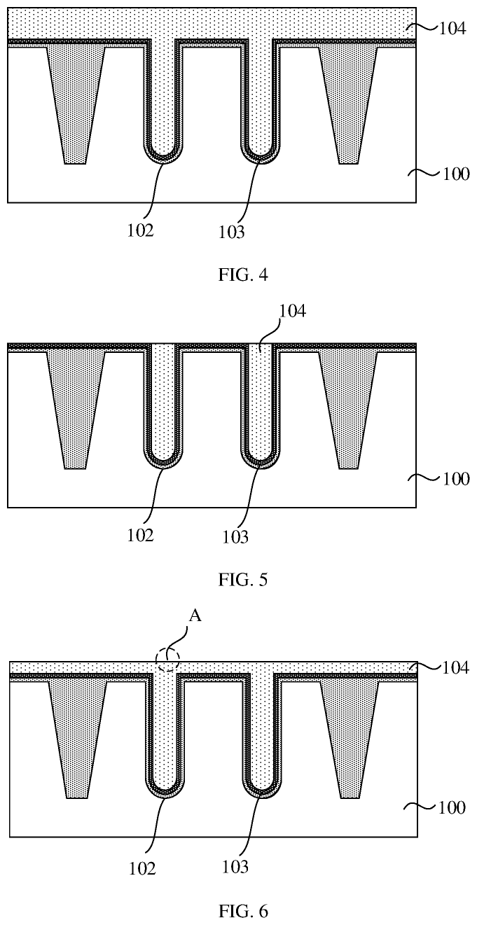

Referring to FIG. 1, in a memory structure are formed a substrate 100 and a metal layer, the metal layer is etched to form a gate electrode 106, and a bitline contact layer 109 is formed.

Since the deposited metal grains are differently sized, this causes relatively severe coarseness at the metal layer; the top surface of the metal layer is uneven, and this causes the difference of ups and downs to be amplified in etching the metal layer to form the gate electrode 106; accordingly, the coarseness on the surface of the gate electrode 106 at the metal grain boundary is relatively severe, the flatness at the top surface of the gate electrode 106 is inferior, and the uneven surface of the gate electrode 106 tends to engender contact short circuit with the bitline contact layer 109.

In order to solve the above problem, embodiments of the present application provide a method of fabricating a memory, whereby, after the metal layer is formed, the metal layer is surface-processed to reduce the difference in heights of the metal grains of the metal layer, and the flatness at the metal layer surface is enhanced; after the metal layer is etched, coarseness on the surface of the gate electrode 106 at the metal grain boundary is relatively small, and this enhances the flatness of the top surface of the gate electrode 106, so there would be no short circuit at the surface of the gate electrode 106 with the bitline contact layer 109.

To make more clear the objectives, technical solutions and advantages of the embodiments of the present application, the various embodiments of the present application will be enunciated in detail below with reference to the accompanying drawings. As should be understood by persons ordinarily skilled in the art, many technical details are proposed in the embodiments of the present application for readers to better understand the present application. However, the technical solution claimed to be protected by the present application can be still realized even without these technical details and various modifications and amendments makeable on the basis of the following embodiments.

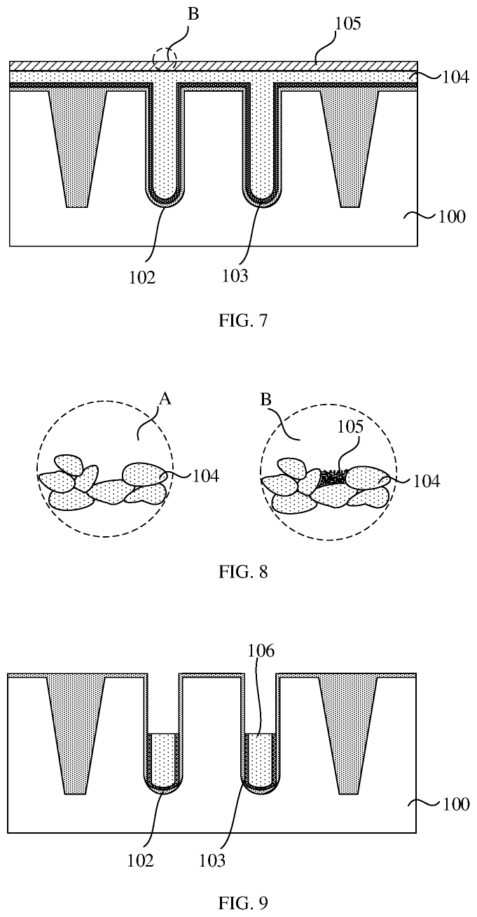

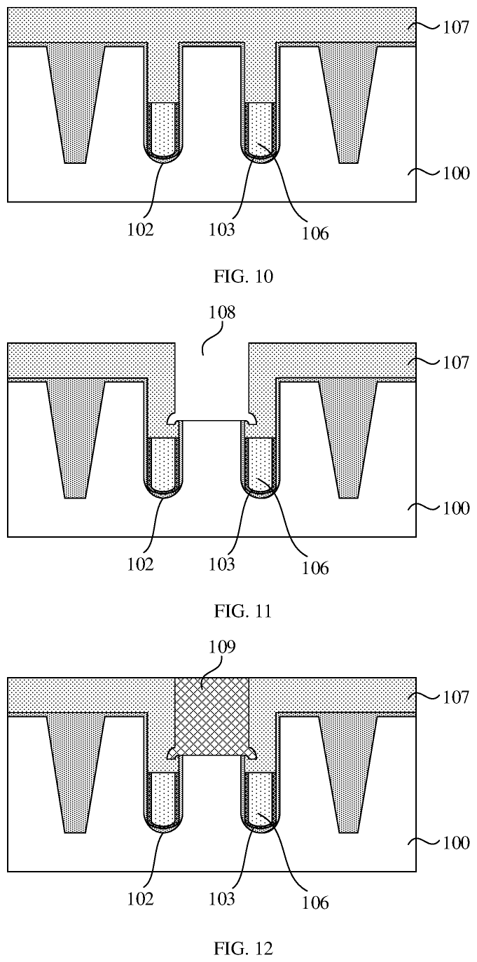

FIGS. 2˜12 are diagrams schematically illustrating structures to which various steps in the method of fabricating a memory as provided by the embodiments of the present application correspond.

Referring to FIG. 2, a substrate 100 is provided, grooves 101 are disposed in the substrate 100, and a gate insulation layer 102 is formed at the surface of each groove 101.

The gate insulation layer 102 can be formed by using a chemical vapor deposition process. The use of the chemical vapor deposition process can form a gate insulation layer 102 with a uniform thickness on the complicatedly shaped substrate 100.

The material of the gate insulation layer 102 can be silica or a high dielectric material, and the high dielectric material can specifically be a ferroelectric ceramic material, a barium titanate based material, or a lead titanate based material.

Referring to FIG. 3, in one example, a diffusion barrier layer 103 is formed at the surface of the gate insulation layer 102. The diffusion barrier layer 103 can prevent diffusion of metal particles in the metal layer 104.

The diffusion barrier layer 103 can be formed by using a chemical vapor deposition process. The use of the chemical vapor deposition process can form a diffusion barrier layer 103 with a uniform thickness on the complicatedly shaped gate insulation layer 102.

The material of the diffusion barrier layer 103 can be a tantalum compound, and specifically be tantalum nitride.

Referring to FIG. 4, a metal layer 104 is formed on the gate insulation layer 102, and the metal layer 104 is at least fully filled in the groove 101.

The metal layer 104 provides a processing basis for subsequently forming the gate electrode 106. In this embodiment, the metal layer 104 is embodied as a tungsten metal layer. In other embodiments, the metal layer 104 can as well be formed as a copper metal layer, an aluminum metal layer, a gold metal layer, or a silver metal layer.

Specifically, the evener the top surface of the metal layer 104 is, the better will be the flatness at the top surface of the gate electrode 106 subsequently formed by etching the metal layer 104. In view of this, gases used to form the tungsten metal layer include silane and tungsten hexafluoride in this embodiment. Thusly, when the tungsten metal layer 104 is formed, the grains of a tungsten metal layer produced by using silane and tungsten hexafluoride are smaller than the grains of a tungsten metal layer produced by using diboron hexahydride and tungsten hexafluoride, coarseness at the surface of the metal layer 104 is decreased, and flatness at the top surface of the metal layer 104 is enhanced.

The flow rate of silane can be 100˜600 sccm, for instance, 200 sccm, 300 sccm or 500 sccm; the flow rate of tungsten hexafluoride can be 50˜500 sccm, for instance, 200 sccm, 300 sccm or 400 sccm; temperature for forming the tungsten metal layer can be 200˜600 degrees Celsius, for instance, 300 degrees Celsius, 400 degrees Celsius or 500 degrees Celsius; and pressure therefor can be 10˜70 torr, for instance, 30 torr, 40 torr or 50 torr. A tungsten metal layer produced by using such processing parameters has smaller grains, hence further enhancing flatness at the top surface of the metal layer 104.

Referring to FIGS. 5 and 6, before the surface-processing, the metal layer 104 at the surface of the substrate 100 is preliminarily flattened in this embodiment.

The preliminary flattening includes performing chemical mechanical polish on the metal layer 104. Thus, the surface of the metal layer 104 can be made more even.

Referring to FIG. 5, in one example, after the preliminary flattening, the metal layer 104 is used only for fully filling in the groove 101.

One of the reasons causing relatively severe coarseness at the surface of the gate electrode 106 is due to the different sizes of grains of the metal layer 104; the surface of the metal layer 104 is uneven, during the subsequent etching process, free radicals of the etchant will accumulate more and more at the valley on the surface of the metal layer 104 due to scattering effect, so that etching rate at the valley will be greater, whereby the difference between peak and valley on the surface of the metal layer 104 becomes increasingly large; the peak is the highest point on the surface of the metal layer 104, while the valley is the lowest point on the surface of the metal layer 104, so the larger the distance etched is, the larger will be the peak-to-valley space of the gate electrode 106 as formed. After the chemical mechanical polish, the metal layer 104 is only fully filled in the groove 101, and the distance etched is relatively short, so this relatively facilitates to improve the flatness at the top surface of the gate electrode 106.

Referring to FIG. 6, in this embodiment, after the preliminary flattening, the thickness of the metal layer 104 located at the surface of the substrate 100 is 10˜20 nm, for instance, 12 nm, 15 nm or 18 nm. The preliminary flattening can arrange the surface of the metal layer 104, whereby grains at the peak are firstly ground, and grains at the valley are thereafter ground, thereby further reducing the difference between the peak and the valley; during the subsequent etching process, free radicals will not accumulate or only slightly accumulate at the valley. Therefore, after the metal layer 104 with a definite thickness located at the surface of the substrate 100 is etched, the top surface of the gate electrode 106 as formed has better flatness.

The above structure can be formed by chemical mechanical polishing, and the specific polishing duration is 10-50 seconds, for instance, 20 seconds, 30 seconds or 40 seconds.

The metal layer 104 is processed by cleaning after chemical mechanical polishing. The cleaning solution used in the cleaning process can be produced with a mixture ratio of 4:1˜1:1 between ammonia and pure water, and the ratio can specifically be 2:1.

Referring to FIG. 7, the metal layer 104 is surface-processed to enhance flatness at the surface of the metal layer 104. After the metal layer 104 is surface-processed, flatness at the top surface of the metal layer 104 is enhanced, and flatness at the surface of the gate electrode 106 formed in the subsequent etching is enhanced.

Surface-processing the metal layer 104 specifically includes a preprocess of the surface of the metal layer 104 using reaction source gas.

The reaction source gas includes chlorine-containing gas that is used to preprocess the metal layer 104 to form a byproduct 105 filled in grain gaps at the surface of the metal layer 104.

Refer to FIG. 8, where A shows the surface of the metal layer 104 before surface-processing, and B shows the surface of the metal layer 104 after surface-processing; the byproduct 105 is filled in the grain gaps at the surface of the metal layer 104, after surface-processing, the peak-to-valley height difference at the surface of the metal layer 104 is decreased.

Reaction source gas is used in this embodiment to preprocess the metal layer 104, and the byproduct formed thereby will be filled in and thus level up the original irregularities at the surface of the metal layer 104, so that, after etching, the peak-to-valley differential is relatively small at the surface of the gate electrode 106, so the surface of the gate electrode 106 would not contact the bitline contact hole to cause short circuit therewith, thus facilitating to solve the problem of unevenness at the top surface of the gate electrode.

In this embodiment, the chlorine-containing gas is boron trichloride and/or chlorine, and the byproduct 105 includes a tungsten chloride product.

In one example, processing parameters of the preprocess include: the flow rate of boron trichloride can be 30˜250 sccm, for instance, 50 sccm, 100 sccm or 200 sccm; the flow rate of chlorine can be 5˜80 sccm, for instance, 20 sccm, 40 sccm or 60 sccm; and the processing duration is 3˜20 seconds, for instance, 5 seconds, 10 seconds or 15 seconds. The peak-to-valley height difference at the surface of a tungsten metal layer 104 produced by using such processing parameters is even smaller, thus further enhancing flatness at the top surface of the metal layer 104.

Referring to FIG. 9, etching is performed to remove the metal layer 104 by a certain thickness to form a gate electrode 106 whose top is lower than a surface of the substrate 100.

Specifically, oxygen, silicon tetrafluoride and sulfur tetrafluoride are used as main gases to etch the metal layer 104.

Oxygen, silicon tetrafluoride and sulfur tetrafluoride are used as main etching gases because etching gases with oxygen, silicon tetrafluoride and sulfur tetrafluoride as main components have such an etching selection ratio that the tungsten metal layer is deeply etched, while the gate insulation layer 102 is substantially not etched, whereby other structures of the memory will not be affected at the same time of obtaining an ideal morphology of the gate electrode 106.

Referring to FIG. 10, an insulation layer 107 is formed on the gate electrode 106, and the insulation layer 107 further covers the surface of the substrate 100.

The material of the insulation layer 107 can be a silicide, and specifically be silicon nitride.

Referring to FIG. 11, the insulation layer 107 between adjacent gate electrodes 106 and the substrate 100 are patterned to form a bitline contact hole 108.

In this embodiment, the bottom width of the bitline contact hole 108 is greater than the top width of the bitline contact hole 108, and the bottom width of the bitline contact layer 109 formed thereby is also greater than the top width of the bitline contact layer 109, so that the area of contact between the bitline contact layer 109 and the substrate 100 becomes larger, and contact resistance between the bitline contact layer 109 and the substrate 100 is decreased.

In other embodiments, the bottom width of the bitline contact hole 108 is equal to the top width of the bitline contact hole 108.

A dry etching process can be employed to etch the insulation layer 107 between adjacent gate electrodes 106 and the substrate 100 to form the bitline contact hole 108. The dry etching process possesses rather good anisotropy, whereby can be obtained a bitline contact hole 108 whose shape more conforms to requirements.

Etching gases include CF₄ and/or Ar. In one example, the flow rate of Ar can be 50˜300 sccm, for instance, 100 sccm, 150 sccm or 200 sccm, and the flow rate of CF₄ can be 50˜200 sccm, for instance, 80 sccm, 130 sccm or 180 sccm.

Referring to FIG. 12, a bitline contact layer 109 is formed between adjacent gate electrodes 106, and the bitline contact hole 108 is fully filled to form the bitline contact layer 109.

In this embodiment, the bottom width of the bitline contact layer 109 is greater than the top width of the bitline contact layer 109, so that the area of contact between the bitline contact layer 109 and the substrate 100 becomes larger, and contact resistance between the bitline contact layer 109 and the substrate 100 is decreased.

In other embodiments, the bottom width of the bitline contact layer 109 is equal to the top width of the bitline contact layer 109.

Embodiments of the present application provide a method of fabricating a memory, whereby, after the metal layer is formed, the metal layer is surface-processed to reduce the difference in heights of the metal grains of the metal layer, and the flatness at the metal layer surface is enhanced; after the metal layer is etched, coarseness on the surface of the gate electrode at the metal grain boundary is relatively small, and this enhances the flatness at the top surface of the gate electrode, so there would be no short circuit at the surface of the gate electrode with the bitline contact layer, thus facilitating to solve the problem of unevenness at the top surface of the semiconductor gate electrode.

As comprehensible to persons ordinarily skilled in the art, the aforementioned embodiments are specific examples to realize the present application, while in actual application, it is possible to make various modifications thereto both in form and in detail without departing from the spirit and scope of the present invention. Any person skilled in the art may make various modifications and amendments without departing from the spirit and scope of the present invention, so the protection scope of the present invention shall be based on the scope defined by the Claims.

1. A method of fabricating a memory, comprising:
providing a substrate, wherein grooves are disposed in the substrate;
forming a gate insulation layer on a surface of each groove;
forming a metal layer on the gate insulation layer, the metal layer being at least fully filled in the groove;
surface-processing the metal layer, to enhance flatness of a surface of the metal layer; and
etching to remove the metal layer by a certain thickness to form a gate electrode whose top is lower than a surface of the substrate.

2. The method of fabricating a memory according to claim 1, wherein the surface-processing is a preprocess of a surface of the metal layer using reaction source gas.

3. The method of fabricating a memory according to claim 2, wherein the reaction source gas includes chlorine-containing gas that is used to preprocess the metal layer to form a byproduct filled in grain gaps at the surface of the metal layer.

4. The method of fabricating a memory according to claim 3, wherein the metal layer includes a tungsten metal layer, that the chlorine-containing gas is at least one of boron trichloride or chlorine, and that the byproduct includes a tungsten chloride product.

5. The method of fabricating a memory according to claim 4, wherein processing parameters of the preprocess include: the boron trichloride has a flow rate of 30-250 sccm, the chlorine has a flow rate of 5-80 sccm, and a processing duration is 3-20 seconds.

6. The method of fabricating a memory according to claim 4, wherein gases used to form the tungsten metal layer include silane and tungsten hexafluoride.

7. The method of fabricating a memory according to claim 6, wherein the silane has a flow rate of 100-600 sccm, that the tungsten hexafluoride has a flow rate of 50-500 sccm, and that temperature for forming the tungsten metal layer is 200-600 degrees Celsius, and pressure therefor is 10-70 torr.

8. The method of fabricating a memory according to claim 1, wherein after the surface-processing, a peak-to-valley height differential at a surface of the metal layer is smaller than or equal to 3 nm.

9. The method of fabricating a memory according to claim 1, wherein before the metal layer is formed, a diffusion barrier layer is formed at the surface of the gate insulation layer.

10. The method of fabricating a memory according to claim 1, wherein before the surface-processing, the metal layer as formed is further disposed at the surface of the substrate, and that the metal layer at the surface of the substrate is preliminarily flattened.

11. The method of fabricating a memory according to claim 10, wherein after the preliminary flattening, the metal layer at the surface of the substrate has a thickness of 10-20 nm.

12. The method of fabricating a memory according to claim 10, wherein the preliminary flattening includes performing chemical mechanical polish on the metal layer.

13. The method of fabricating a memory according to claim 1, wherein after forming the gate electrode, further included is a step of forming a bitline contact layer between adjacent gate electrodes, wherein a bottom width of the bitline contact layer is greater than a top width of the bitline contact layer.

14. The method of fabricating a memory according to claim 13, wherein processing steps for forming the bitline contact layer include: forming an insulation layer on the gate electrodes, the insulation layer further covering the surface of the substrate; patterning the insulation layer between adjacent gate electrodes and the substrate to form a bitline contact hole, a bottom width of the bitline contact hole being greater than a top width of the bitline contact hole; and fully filling the bitline contact hole to form the bitline contact layer.

15. The method of fabricating a memory according to claim 14, wherein a dry etching process is employed to etch the insulation layer between adjacent gate electrodes and the substrate, that etching gases include at least one of CF₄ or Ar, that a flow rate of Ar is 50-300 sccm, and that a flow rate of CF₄ is 50-200 sccm.
